(19) United States
(12) Patent Application Publication
(10) Pub. No.: US 2022/0310682 A1
(43) Pub. Date: Sep. 29, 2022

(54) SEMICONDUCTOR DEVICE AND MANUFACTURING METHOD THEREFOR

(71) Applicant: WUHAN XINXIN SEMICONDUCTOR MANUFACTURING CO., LTD., Wuhan (CN)

(72) Inventors: Fan YANG, Wuhan (CN); Sheng HU, Wuhan (CN)

(21) Appl. No.: 17/829,182

(22) Filed: May 31, 2022

Related U.S. Application Data
(63) Continuation of application No. PCT/CN2020/128317, filed on Nov. 12, 2020.

(30) Foreign Application Priority Data
Dec. 2, 2019 (CN) 201911214656.2

(51) Int. Cl. H01L 27/146

(52) U.S. Cl. CPC H01L 27/14603; H01L 27/14685; H01L 27/14643; H01L 31/107

(57) ABSTRACT

A semiconductor device and a method of manufacturing the semiconductor device are disclosed. The method includes: forming a trench fill structure in a pixel region of a substrate; covering a surface of the substrate in the pixel region with a buffer dielectric layer; etching the buffer dielectric layer to form a first opening exposing at least part of the substrate around a top side wall portion of the trench fill structure and/or at least a top portion of the trench fill structure; filling a first conductive metal layer in the first opening in such a manner that it is electrically connected to the exposed part of the substrate and/or the exposed portion of the trench fill structure; and forming a metal grid layer on the buffer dielectric layer so that it is electrically connected to the first conductive metal layer.

### CROSS-REFERENCES TO RELATED APPLICATION

This application is a continuation of International Patent Application No. PCT/CN2020/128317, filed on Nov. 12, 2020, entitled “SEMICONDUCTOR DEVICE AND MANUFACTURING METHOD THEREFOR”, and which claims priority of Application No. 201911214656.2 filed in China on Dec. 2, 2019 under 35 U.S.C. § 119 the entire contents of all of which are incorporated herein by reference.

### TECHNICAL FIELD

The present invention relates to the field of semiconductor integrated circuit fabrication and, in particular, to a semiconductor device and a method of manufacturing the device.

### BACKGROUND

During the fabrication of a back-side illuminated CMOS image sensor (BSI-CIS), the combined use of deep trench isolation (DTI) and backside metal grid (BMG) techniques enables better BSI-CIS optical properties.

However, in existing BSI-CIS fabrication processes, due to the presence of a buffer dielectric layer between a metal grid formed in a pixel region and an underlying substrate and deep trench fill structure, the metal grid can be connected to the underlying substrate and deep trench fill structure only physically but not electrically, leading to impossible optimization or improvement of the BSI-CIS's electrical performance.

Therefore, there is urgent need to modify the metal grid fabrication in the pixel region to enable electrical connection between the metal grid and the underlying substrate and/or trench fill structure and thereby obtain a semiconductor device with optimized and improved electrical performance.

### SUMMARY OF THE INVENTION

It is an aim of the present invention to provide a semiconductor device and a method of manufacturing the semiconductor device, in which a metal grid layer is electrically connected to an exposed part of a substrate and/or an exposed portion of a trench fill structure, thus resulting in optimized and improved electrical performance of the semiconductor device.

In pursuit of this aim, the present invention provides a method of manufacturing a semiconductor device, including:

providing a substrate with a pixel region;

forming a trench fill structure in the pixel region of the substrate;

covering a surface of the substrate in the pixel region with a buffer dielectric layer so that the trench fill structure is embedded in the buffer dielectric layer;

etching the buffer dielectric layer to form a first opening exposing at least part of the substrate around a top side wall portion of the trench fill structure and/or at least a top portion of the trench fill structure;

filling a first conductive metal layer in the first opening so that the first conductive metal layer is electrically connected to the exposed part of the substrate and/or the exposed portion of the trench fill structure; and

forming a metal grid layer on the buffer dielectric layer so that the metal grid layer is electrically connected to the first conductive metal layer.

Optionally, the step of forming the trench and the trench fill structure in the pixel region of the substrate may include:

covering the surface of the substrate in the pixel region with a pad oxide layer;

forming a first patterned photoresist layer on the pad oxide layer and, with the first patterned photoresist layer serving as a mask, etching through the pad oxide layer and at least a partial thickness of the substrate, thereby forming the trench in the pixel region of the substrate;

removing the first patterned photoresist layer and the pad oxide layer;

successively forming a first isolating oxide layer, the high-k dielectric layer and a second isolating oxide layer both in the trench and on the surface of the substrate;

filling the fill material in the trench in such a manner that the fill material also covers the second isolating oxide layer outside the trench; and

performing an etching or chemical mechanical polishing process to remove the fill material, the second isolating oxide layer, the high-k dielectric layer and the first isolating oxide layer above the surface of the substrate outside the trench, or to remove only the fill material above the surface of the substrate outside the trench, thereby forming the trench fill structure in the trench.

Optionally, the fill material may include a second conductive metal layer made of a material that is the same as that of the first conductive metal layer, wherein the exposure of at least a top portion of the trench fill structure in the first opening includes: exposure of the second conductive metal layer at a top side wall portion of the trench fill structure in the first opening that is so formed as to surround the top side wall portion of the trench fill structure; and/or exposure of part or the entirety of a top surface of the second conductive metal layer in the trench fill structure in the first opening that resides on a top surface of the trench fill structure.

Optionally, the step of forming the first opening by etching the buffer dielectric layer includes:

forming a second patterned photoresist layer on the buffer dielectric layer and, with the second patterned photoresist layer serving as a mask, etching the buffer dielectric layer, thereby forming the first opening in the buffer dielectric layer in the pixel region, the first opening exposing at least part of the substrate around a top side wall portion of the trench fill structure and/or at least a top portion of the trench fill structure; and

removing the second patterned photoresist layer.

Optionally, the step of filling the first conductive metal layer in the first opening includes:

forming the first conductive metal layer so that it covers the buffer dielectric layer and fills up the first opening; and

performing an etching or chemical mechanical polishing process to remove the first conductive metal layer over the substrate, with the first conductive metal layer in the first opening being retained, which is electrically connected to the exposed part of the substrate and/or the exposed portion of the trench fill structure.

Optionally, the step of forming the metal grid layer on the buffer dielectric layer includes:

forming a third conductive metal layer on the buffer dielectric layer, which is made of a material that is different from that of the first conductive metal layer, so that the first conductive metal layer is buried in the third conductive metal layer;

forming a third patterned photoresist layer on the third conductive metal layer and, with the third patterned photoresist layer serving as a mask, etching the third conductive metal layer, thus forming the metal grid layer in the pixel region, which is electrically connected to the first conductive metal layer; and

removing the third patterned photoresist layer.

Optionally, the substrate may further have a pad region peripheral to the pixel region, wherein a metal interconnection is formed in the pad region of the substrate and a plug structure above the metal interconnection, the plug structure being electrically connected at the bottom to the metal interconnection.

Optionally, the plug structure may be formed in the pad region of the substrate subsequent to the formation of the trench fill structure and prior to the covering of the surface of the substrate in the pixel region with the buffer dielectric layer.

Optionally, in the step of covering the surface of the substrate in the pixel region with the buffer dielectric layer, the buffer dielectric layer may be so formed as to further cover the surface of the substrate in the pad region so that the plug structure is embedded in the buffer dielectric layer, wherein at the same time when the first opening is formed by etching the buffer dielectric layer in the pixel region, the buffer dielectric layer in the pad region is also etched to form a second opening exposing part of a top surface of the plug structure, wherein the first conductive metal layer is so filled in the first opening that it also fills the second opening and is electrically connected in the second opening to the exposed top surface part of the plug structure; and wherein at the same time when the metal grid layer is formed on the buffer dielectric layer in the pixel region, a pad structure is formed on the buffer dielectric layer in the pad region so as to be electrically connected to the first conductive metal layer in the second opening.

The present invention also provides a semiconductor device, including:

a substrate with a pixel region, the substrate including a trench formed in the pixel region;

a trench fill structure formed in the pixel region of the substrate;

a buffer dielectric layer formed on the surface of the substrate in the pixel region, the buffer dielectric layer including a first opening exposing at least part of the substrate around a top side wall portion of the trench fill structure and/or at least a top portion of the trench fill structure;

a first conductive metal layer filled in the first opening so as to be electrically connected to the exposed part of the substrate and/or the exposed portion of the trench fill structure; and

a metal grid layer formed on the buffer dielectric layer so as to be electrically connected to the first conductive metal layer.

Optionally, the trench fill structure may include a first isolating oxide layer, the high-k dielectric layer, a second isolating oxide layer, which are sequentially stacked over a surface of the trench in the substrate, and the fill material filled in the trench, the first isolating oxide layer, wherein the high-k dielectric layer and the second isolating oxide layer are situated at least between the side wall of the fill material and the substrate.

Optionally, the fill material may include a second conductive metal layer made of a material that is the same as that of the first conductive metal layer, wherein the exposure of at least a top portion of the trench fill structure in the first opening includes: exposure of the second conductive metal layer at a top side wall portion of the trench fill structure in the first opening that is so formed as to surround the top side wall portion of the trench fill structure; and/or exposure of part or the entirety of a top surface of the second conductive metal layer in the trench fill structure in the first opening that resides on a top surface of the trench fill structure.

Optionally, the high-k dielectric layer may have a k value of greater than 7.

Optionally, the substrate may further have a pad region peripheral to the pixel region, wherein a metal interconnection is formed in the pad region of the substrate and a plug structure above the metal interconnection, the plug structure being electrically connected at the bottom to the metal interconnection.

Optionally, a through hole may be formed in the pad region of the substrate, the through hole exposing at least part of a top surface of the metal interconnection, wherein the plug structure includes a third isolating oxide layer on a side wall of the through hole and a fourth conductive metal layer which fills up the through hole.

Optionally, the buffer dielectric layer may further cover the surface of the substrate in the pad region and include a second opening exposing at least a top portion of the plug structure, wherein the first conductive metal layer is further filled in the second opening so as to be electrically connected in the second opening to the exposed top surface part of the plug structure, and wherein a pad structure is formed on the buffer dielectric layer in the pad region so as to be electrically connected to the first conductive metal layer in the second opening.

Embodiments of the present invention offer the following advantages over the prior art:

1. The method of the present invention includes: forming a trench fill structure in a pixel region of a substrate, wherein a high-k dielectric layer is sandwiched between a side wall of a fill material in the trench fill structure and the substrate; covering a surface of the substrate in the pixel region with a buffer dielectric layer so that the trench fill structure is embedded in the buffer dielectric layer; etching the buffer dielectric layer to form a first opening exposing at least part of the substrate around a top side wall portion of the trench fill structure and/or at least a top portion of the trench fill structure; filling a first conductive metal layer in the first opening so that the first conductive metal layer is electrically connected to the exposed part of the substrate and/or the exposed portion of the trench fill structure; and forming a metal grid layer on the buffer dielectric layer so that the metal grid layer is electrically connected to the first conductive metal layer. Thus, the metal grid layer is electrically connected to the exposed part of the substrate and/or the exposed portion of the trench fill structure, resulting in optimized and improved electrical performance of the semiconductor device. Further, the high-k dielectric layer sandwiched between the side wall of the fill material and the substrate additionally optimizes the performance of the semiconductor device.

2. The semiconductor device of the present invention includes: a trench fill structure formed in a pixel region of a substrate, the trench fill structure including a fill material filled in a trench in the substrate and a high-k dielectric layer situated between a side wall of the fill material and the substrate; a buffer dielectric layer formed on the surface of the substrate in the pixel region, the buffer dielectric layer including a first opening exposing at least part of the substrate around a top side wall portion of the trench fill structure and/or at least a top portion of the trench fill structure; a first conductive metal layer filled in the first opening so as to be electrically connected to the exposed part of the substrate and/or the exposed portion of the trench fill structure; and a metal grid layer formed on the buffer dielectric layer so as to be electrically connected to the first conductive metal layer. Thus, the metal grid layer is electrically connected to the exposed part of the substrate and/or the exposed portion of the trench fill structure, resulting in optimized and improved electrical performance of the semiconductor device. Further, the high-k dielectric layer sandwiched between the side wall of the fill material and the substrate additionally optimizes the performance of the semiconductor device.

### BRIEF DESCRIPTION OF THE DRAWINGS

FIGS. 1a to 1f are schematic illustrations of a device being fabricated in a semiconductor device fabrication process;

FIG. 2 is a flowchart of a method of manufacturing a semiconductor device according to an embodiment of the present invention;

FIGS. 3a to 3j are schematic diagrams showing a device being fabricated in a first embodiment of the method of FIG. 2;

FIGS. 4a to 4f are schematic diagrams showing a device being fabricated in a second embodiment of the method of FIG. 2;

FIGS. 5a to 5f are schematic diagrams showing a device being fabricated in a third embodiment of the method of FIG. 2;

FIGS. 6a to 6h are schematic diagrams showing a device being fabricated in a fourth embodiment of the method of FIG. 2;

FIG. 7 is a schematic diagram showing a device fabricated by a fifth embodiment of the method of FIG. 2; and

FIGS. 8a to 8q are schematic diagrams showing a device being fabricated in a sixth embodiment of the method of FIG. 2.

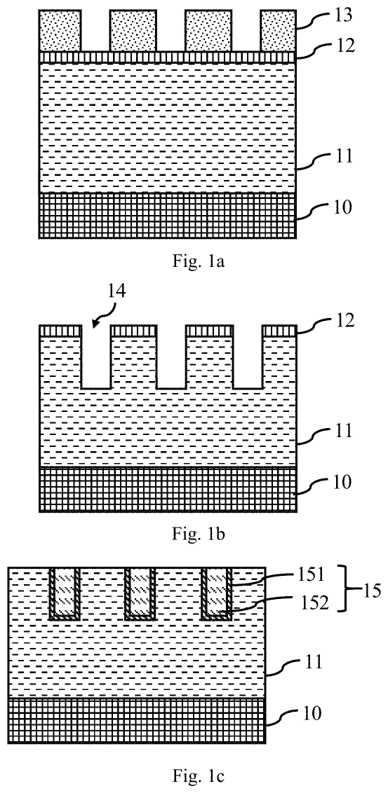

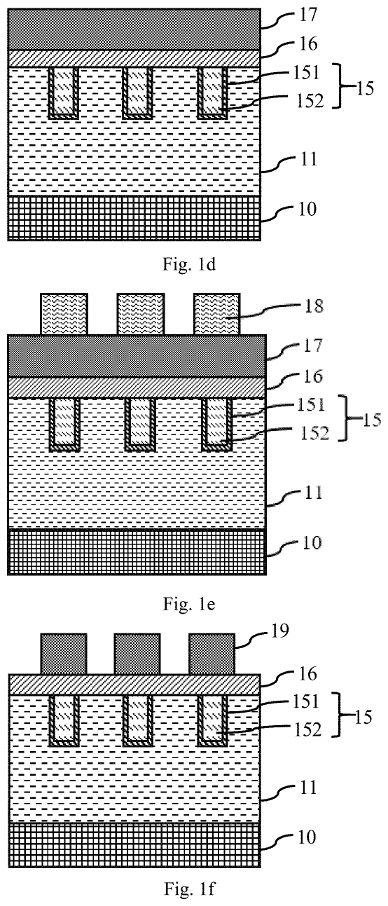

The following is a list of reference numerals used in FIGS. 1a to 8q:

10—Substrate; 11—Pixel Region; 12—Pad Oxide Layer; 13—First Patterned Photoresist Layer; 14—Trench; 15—Trench Fill Structure; 151—Isolating Oxide Layer; 152—Conductive Metal Layer; 16—Buffer Oxide Layer; 17—Metal Grid Film; 18—Second Patterned Photoresist Layer; 19—Metal Grid Layer;

20—Substrate; 21—Pixel Region; 211—Trench; 212—Trench fill Structure; 2121—First Isolating Oxide Layer; 2122—High-k Dielectric Layer; 2123—Second Isolating Oxide Layer; 2124—Second Conductive Metal Layer; 2131, 2132, 2133, 2134—First Opening; 214—Metal Grid Layer; 22—Pad Region; 221—Metal interconnection; 222—Third Opening; 223—Through Hole; 224—Plug Structure; 2241—Third Isolating Oxide Layer; 2242—Fourth Conductive Metal Layer; 225—Second Opening; 226—Pad Structure; 23—Pad Oxide Layer; 24—First Patterned Photoresist Layer; 25—Buffer Dielectric Layer; 251—First Buffer Dielectric Layer; 252—Second Buffer Dielectric Layer; 253—Third Buffer Dielectric Layer; 261, 262, 263, 264—Second Patterned Photoresist Layer; 271, 272, 273, 274, 275—First Conductive Metal Layer; 28—Third Conductive Metal Layer; 29—Third Patterned Photoresist Layer; 30—Fourth Patterned Photoresist Layer; 31—Fifth Patterned Photoresist Layer.

### DETAILED DESCRIPTION

A metal grid layer is made in a pixel region in the manner as detailed below.

As shown in FIG. 1a, a substrate 10 with the pixel region 11 is provided.

As shown in FIGS. 1a and 1b, a pad oxide layer 12 is formed in the pixel region 11, and a first patterned photoresist layer 13 on the pad oxide layer 12. With the first patterned photoresist layer 13 serving as a mask, an etching process is performed, which proceeds through the pad oxide layer 12 and a fractional thickness of the substrate 10 in the pixel region 11, forming a trench 14 in the pixel region 11 of the substrate 10. The first patterned photoresist layer 13 is then removed.

As shown in FIG. 1c, an isolating oxide layer 151 is formed over surfaces of the trench 14 and pad oxide layer 12, and a conductive metal layer 152 is filled in the trench 14 so as to also cover the pad oxide layer 12. A chemical mechanical polishing process may be employed to remove the conductive metal layer 152, the isolating oxide layer 151 and the pad oxide layer 12 above the substrate 10, resulting in the formation of a trench fill structure 15 in the trench 14. The trench fill structure 15 includes the isolating oxide layer 151 and the conductive metal layer 152.

As shown in FIG. 1d, a buffer oxide layer 16 and a metal grid film 17 are successively formed over the substrate 10.

As shown in FIGS. 1e and 1f, a second patterned photoresist layer 18 is formed on the metal grid film 17. With the second patterned photoresist layer 18 serving as a mask, the metal grid film 17 is etched so that the metal grid layer 19 is formed on the buffer oxide layer 16. The second patterned photoresist layer 18 is then removed. The metal grid layer 19 is located above and aligned with the trench fill structure 15.

As apparent from the description of the above steps, due to the presence of the buffer oxide layer between the metal grid layer and the underlying substrate and trench fill structure, the metal grid layer in the pixel region can be connected to the underlying substrate and trench fill structure only physically but not electrically, making it impossible to optimize or improve electrical performance of the semiconductor device. In view of this, the present invention proposes a semiconductor device and a method of manufacturing it, in which electrical connection of the metal grid layer is enabled with the underlying substrate and trench fill structure, allowing the semiconductor device to have optimized and improved electrical performance.

By electrically connecting the metal grid layer with the substrate to form a conductive loop, it is possible to apply a voltage to the backside of the substrate, so that the semiconductor device provided in the present embodiment can be applied to some special devices, such as TOF SPAD devices. TOF SPAD is short for Single-photon avalanche diodes based on time-of-flight, which need to work in Geiger mode, and generally requires a voltage of 20V and above on the backside of the substrate of the TOF SPAD device.

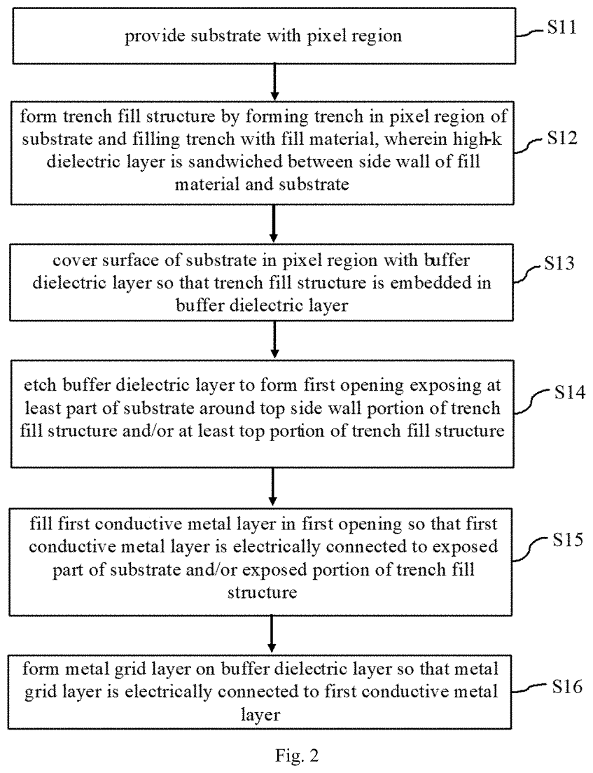

In order that objects, advantages and features of the present invention become more apparent, the semiconductor device and method proposed in the invention will be described in greater detail below with reference to FIGS. 2 to 8q. Note that the drawings are provided in a very simplified form not necessarily drawn to exact scale for the only purpose of helping to explain the disclosed embodiments in a more convenient and clearer way.

In an embodiment of the present invention, there is provided a method of manufacturing a semiconductor device, which, as shown in FIG. 2, a flowchart thereof, includes the steps of:

Step S11, providing a substrate with a pixel region;

Step S12, forming a trench in the pixel region of the substrate and filling the trench with a fill material, thus forming a trench fill structure, wherein a high-k dielectric layer is sandwiched between a side wall of the fill material and the substrate;

Step S13, covering a surface of the substrate in the pixel region with a buffer dielectric layer so that the trench fill structure is embedded in the buffer dielectric layer;

Step S14, etching the buffer dielectric layer to form a first opening exposing at least part of the substrate around a top side wall portion of the trench fill structure and/or at least a top portion of the trench fill structure;

Step S15, filling a first conductive metal layer in the first opening so that the first conductive metal layer is electrically connected to the exposed part of the substrate and/or the exposed portion of the trench fill structure; and

Step S16, forming a metal grid layer on the buffer dielectric layer so that the metal grid layer is electrically connected to the first conductive metal layer.

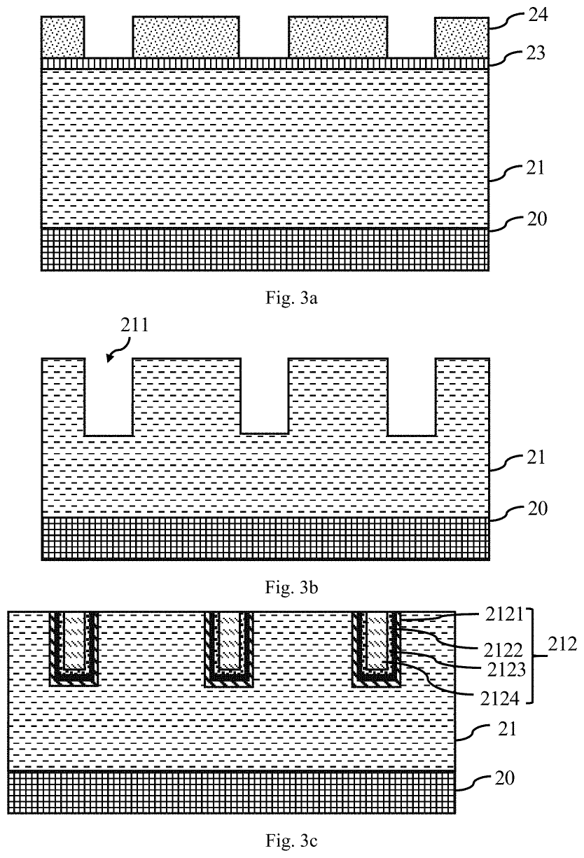

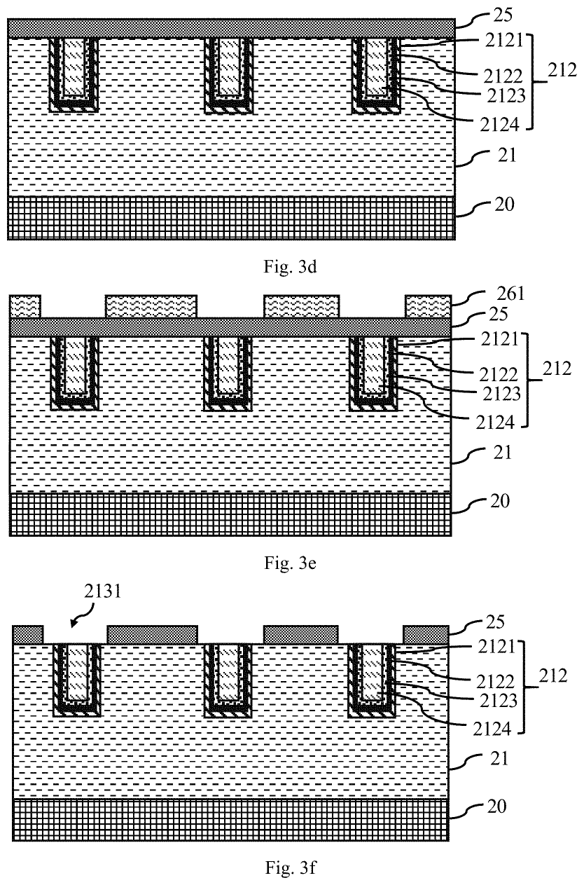

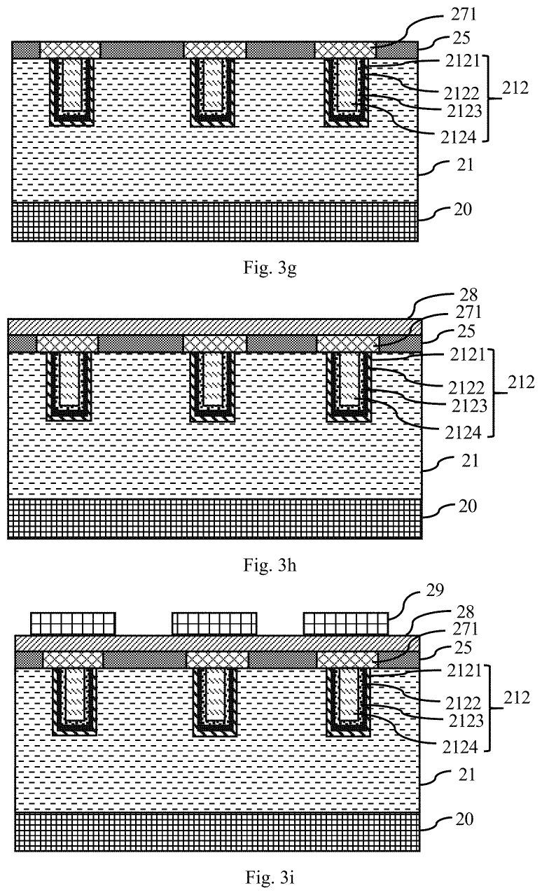

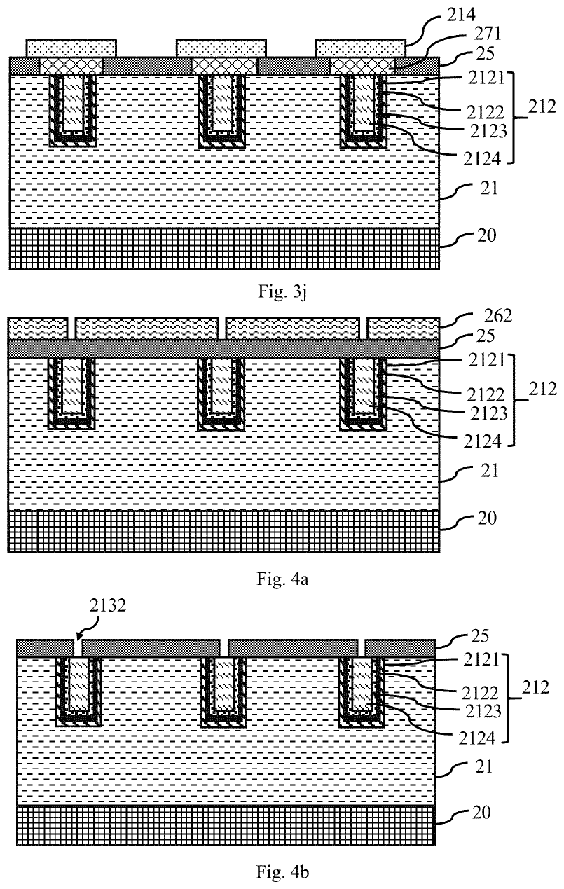

A more detailed description of the method of the present invention is set forth below with reference to FIGS. 3a to 8q, which are all schematic longitudinal cross-sectional views of the semiconductor device being fabricated.

In step S11, a substrate 20 with a pixel region 21 is provided. The substrate 20 may be any suitable material well known to those skilled in the art. For example, it may be at least one of silicon (Si), germanium (Ge), germanium silicon (SiGe), semiconductor on insulator (SOI), silicon carbide (SiC), germanium silicon carbide (SiGeC), indium arsenide (InAs), gallium arsenide (GaAs), indium phosphide (InP) or other III-V compound semiconductors.

In step S2, a trench 211 is formed in the pixel region 21 of the substrate 20, and a fill material is filled in the trench 211, thus forming a trench fill structure 212. A high-k dielectric layer 2122 is sandwiched between a side wall of the fill material and the substrate 20. The trench 211 may be a deep trench with a depth of 1-5 μm. It is to be noted that the depth of the trench 211 is not limited to being within the above range and may be appropriately determined according to performance requirements for the semiconductor device. The trench fill structure 212 may serve to isolate components in the pixel region 21 of the substrate 20. The high-k dielectric layer 2122 is preferred to have a k (dielectric permittivity) value of greater than 7. Materials from which the high-k dielectric layer 2122 can be made may include, but are not limited to, nitrides or metal oxides such as silicon nitride, silicon oxynitride, titanium dioxide, tantalum pentoxide, etc. The high-k dielectric layer 2122 operates at a voltage in a different band and has different charge properties and can thus change the charge in the substrate 20 and reduce a dark current that may produce noise harmful to the performance of the semiconductor device.

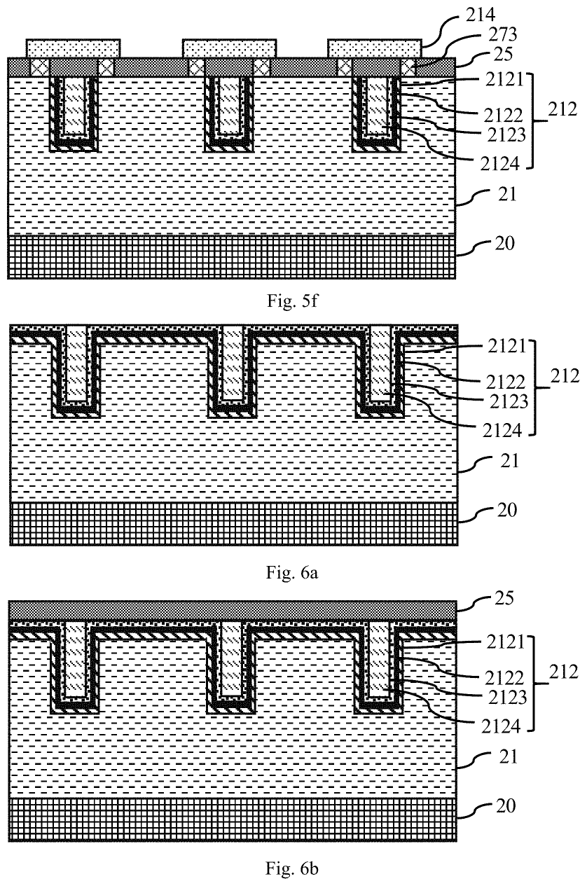

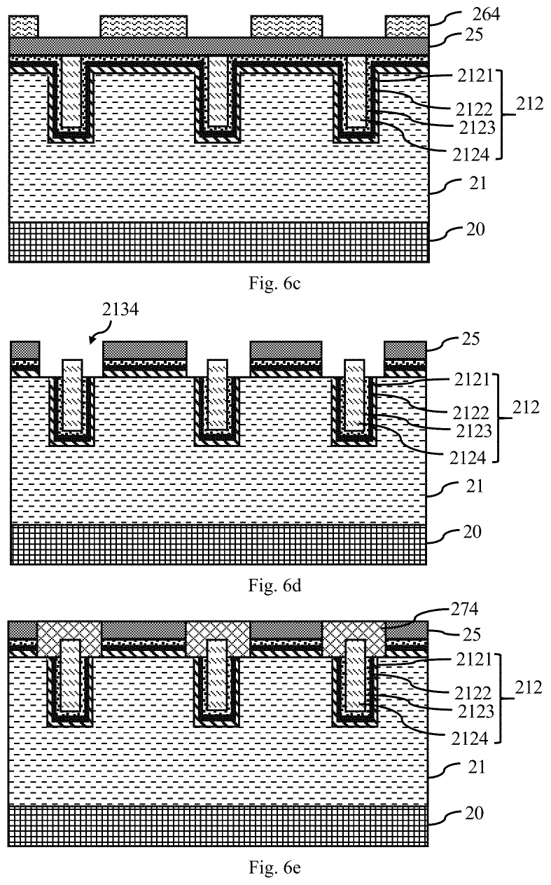

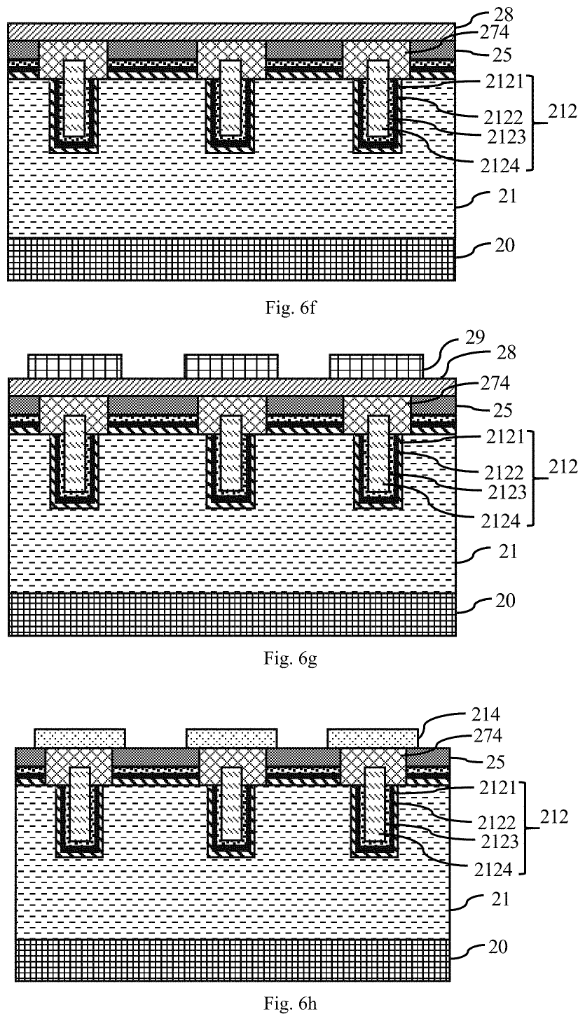

The step in which the trench 211 and the trench fill structure 212 are formed in the pixel region 21 of the substrate 20 includes: first, as shown in FIG. 3a, covering a surface of the substrate 20 in the pixel region 21 with a pad oxide layer 23, which is intended to protect the surface of the substrate 20 during the subsequent photolithographic formation of the first patterned photoresist layer 24; then, as shown in FIGS. 3a and 3b, forming the first patterned photoresist layer 24 on the pad oxide layer 23 and, with the first patterned photoresist layer 24 serving as a mask, etching through the pad oxide layer 23 and at least a partial thickness of the substrate 20, thereby forming the trench 211 in the pixel region 21 of the substrate 20; subsequently, removing the first patterned photoresist layer 24 and the pad oxide layer 23; next, successively forming a first isolating oxide layer 2121, the high-k dielectric layer 2122 and a second isolating oxide layer 2123 both in the trench 211 and over the surface of the substrate 20, wherein the first isolating oxide layer 2121, the high-k dielectric layer 2122 and the second isolating oxide layer 2123 in the trench 211 may reside either only on a side wall of the trench 211 or on both the side wall and a bottom wall of the trench 211; afterwards, filling the fill material in the trench 211 so that it also covers the second isolating oxide layer 2123 surrounding the trench 211; and then performing an etching or chemical mechanical polishing process to remove the fill material, the second isolating oxide layer 2123, the high-k dielectric layer 2122 and the first isolating oxide layer 2121 above the surface of the substrate 20 around the trench 211 (as shown in FIG. 3c), or only the fill material above the surface of the substrate 20 around the trench 211 (as shown in FIG. 6a), thus forming the trench fill structure 212 in the trench 211. In FIG. 6a, the first isolating oxide layer 2121, the high-k dielectric layer 2122 and second isolating oxide layer 2123 are shown as remaining over the substrate 20.

The fill material may include a dielectric material, or a metallic material, or both. When the fill material is a metallic material, as shown in FIG. 3c, the trench fill structure 212 includes the first isolating oxide layer 2121, the high-k dielectric layer 2122 and the second isolating oxide layer 2123, all formed over the surface of the trench 211, and a second conductive metal layer 2124 that fills up the trench 211 (i.e., the fill material provides the second conductive metal layer 2124). The dielectric material may include at least one of silica, silicon nitride, ethyl silicate, borosilicate glass, phosphosilicate glass, boro-phospho-silicate glass and silicon oxynitride, and the metallic material may include at least one of tungsten, nickel, aluminum, silver, gold and titanium.

Additionally, a top surface of the trench fill structure 212 may be flush with the top surface of the substrate 20. Alternatively, the top surface of the trench fill structure 212 may be higher than the top surface of the substrate 20. Alternatively, only a top surface of the fill material in the trench fill structure 212 may be higher than the top surface of the substrate 20.

In step S13, the surface of the substrate 20 in the pixel region 21 is covered with a buffer dielectric layer 25 so that the trench fill structure 212 is embedded in the buffer dielectric layer 25, as shown in FIG. 3d. The buffer dielectric layer 25 may be formed of a material including at least one of silica, silicon nitride, ethyl silicate, borosilicate glass, phosphosilicate glass, boro-phospho-silicate glass and silicon oxynitride. As shown in FIGS. 6a and 6b, if only the fill material above the surface of the substrate 20 around the trench 211 is removed, with the first isolating oxide layer 2121, the high-k dielectric layer 2122 and the second isolating oxide layer 2123 still remaining above the surface of the substrate 20, then it can be interpreted that the first isolating oxide layer 2121, the high-k dielectric layer 2122 and the second isolating oxide layer 2123 form part of the buffer dielectric layer 25.

In step S14, the buffer dielectric layer 25 is etched to form a first opening exposing at least part of the substrate 20 around a top side wall portion of the trench fill structure 212, at least a top portion of the trench fill structure 212, or both.

The exposure of at least part of the substrate 20 around a top side wall portion of the trench fill structure 212 in the first opening 214 means that the first opening is so formed as to at least surround the top of the trench fill structure 212 so that at least part of the substrate 20 around the top of the trench fill structure 212 is exposed.

The exposure of at least a top portion of the trench fill structure 212 in the first opening 214 may include: when the top surface of the trench fill structure 212 is raised over the top surface of the substrate 20, and if the first opening surrounds only the top side wall portion of the trench fill structure 212 so that the first isolating oxide layer 2121 is exposed at the top side wall portion of the trench fill structure 212, exposure of also part of the substrate 20 around the top side wall portion of the trench fill structure 212 in the first opening 214; when only the top surface of the fill material in the trench fill structure 212 is raised over the top surface of the substrate 20, and if the first opening 214 surrounds only the top side wall portion of the trench fill structure 212, exposure of the fill material in the trench fill structure 212 at the top side wall portion; when the top surface of the trench fill structure 212 is raised over or flush with the top surface of the substrate 20, and if the first opening 214 resides on the top surface of the trench fill structure 212, exposure of part or the entirety of the top surface of the trench fill structure 212, including exposure of part or the entirety of the top surface of the fill material, or exposure of both part or the entirety of the top surface of the fill material and part or the entirety of top surface(s) of the first isolating oxide layer 2121 and/or the high-k dielectric layer 2122 and/or the second isolating oxide layer 2123; and when the top surface of the trench fill structure 212 is raised over the top surface of the substrate 20, exposure of both the first isolating oxide layer 2121, the high-k dielectric layer 2122, the second isolating oxide layer 2123 or the fill material in the trench fill structure 212 at the top side wall portion and part or the entirety of the top surface of the trench fill structure 212.

When the fill material includes the second conductive metal layer 2124, the exposure of at least a top portion of the trench fill structure 212 in the first opening may include: exposure of the second conductive metal layer 2124 at the top side wall portion of the trench fill structure 212 in the first opening 214 that is so formed as to surround the top side wall portion of the trench fill structure 212; or exposure of part or the entirety of the top surface of the second conductive metal layer 2124 in the trench fill structure 212 in the first opening 214 that resides on the top surface of the trench fill structure 212; or exposure of both the second conductive metal layer 2124 in the trench fill structure 212 at the top side wall portion and part or the entirety of the top surface of the second conductive metal layer 2124 in the trench fill structure 212 in the first opening 214.

Different methods for forming the first opening in the above various scenarios of exposure of the underlying structure in the first opening will be exemplified below. FIGS. 3e to 3j, FIGS. 4a to 4f and FIGS. 5a to 5f show the scenarios where the top surface of the trench fill structure 212 is flush with the top surface of the substrate 20. FIGS. 6c to 6h show the scenario where the top surface of the trench fill structure 212 is raised over the top surface of the substrate 20, with the first isolating oxide layer 2121, the high-k dielectric layer 2122 and the second isolating oxide layer 2123 remaining above the substrate 20.

Referring to FIGS. 3e to 3f, the formation of the first opening 2131 may include the steps of: forming a second patterned photoresist layer 261 on the buffer dielectric layer 25 (as shown in FIG. 3e); and with the second patterned photoresist layer 261 serving as a mask, etching the buffer dielectric layer 25, thus forming the first opening 2131 in the buffer dielectric layer 25 in the pixel region 21, in which part of the substrate 20 around a top side wall portion of the trench fill structure 212 and the entire top surface of the trench fill structure 212 are exposed, as shown in FIG. 3f.

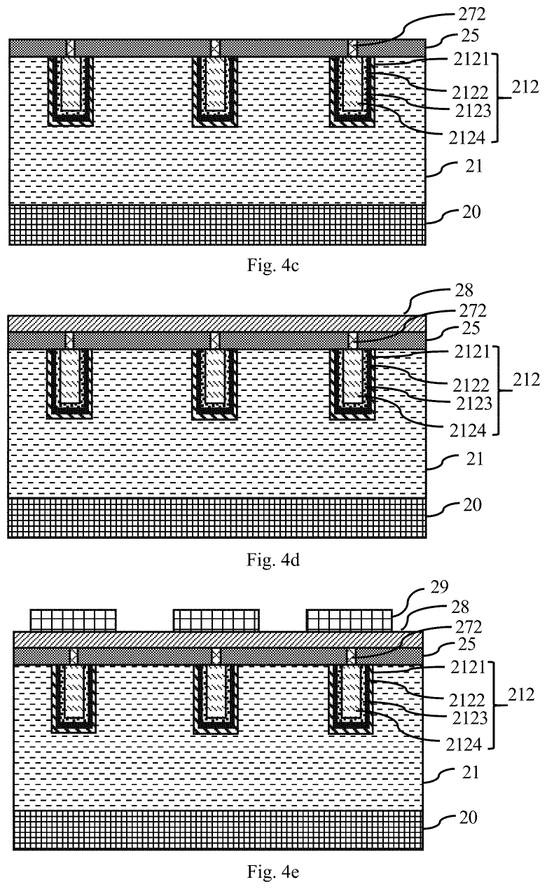

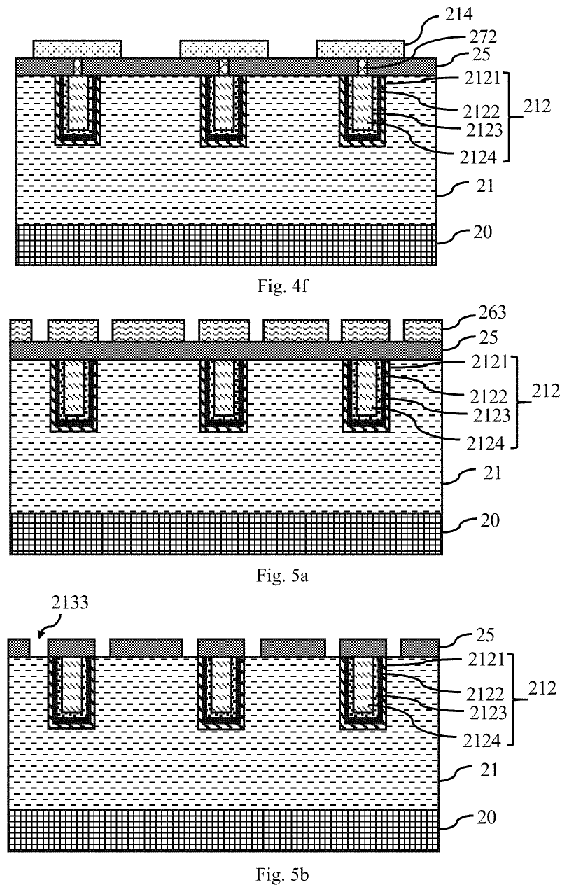

Alternatively, referring to FIGS. 4a to 4b, the formation of the first opening 2132 may include the steps of: forming a second patterned photoresist layer 262 on the buffer dielectric layer 25 (as shown in FIG. 4a); and with the second patterned photoresist layer 262 serving as a mask, etching the buffer dielectric layer 25, thus forming the first opening 2132 in the buffer dielectric layer 25 in the pixel region 21, in which part of the top surface of the trench fill structure 212, such as part of the top surface of the fill material, is exposed, as shown in FIG. 4b. If the fill material is the second conductive metal layer 2124, then part of the top surface of the second conductive metal layer 2124 in the trench fill structure 212 is exposed in the first opening 2132.

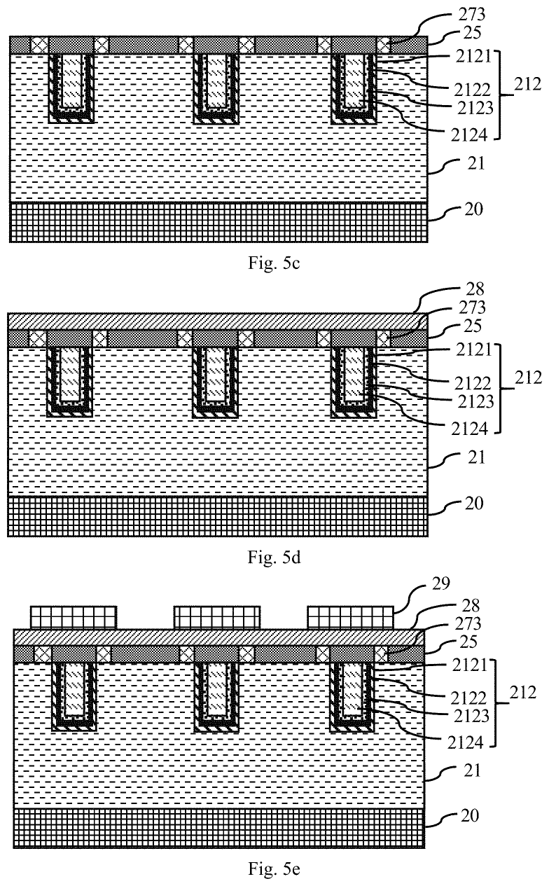

Alternatively, referring to FIGS. 5a to 5b, the formation of the first opening 2133 may include the steps of: forming a second patterned photoresist layer 263 on the buffer dielectric layer 25 (as shown in FIG. 5a); and with the second patterned photoresist layer 263 serving as a mask, etching the buffer dielectric layer 25, thus forming the first opening 2133 in the buffer dielectric layer 25 in the pixel region 21, as shown in FIG. 5b, in which part of the substrate 20 around a top side wall portion of the trench fill structure 212 is exposed.

Alternatively, referring to FIGS. 6c to 6d, the formation of the first opening 2134 may include the steps of: forming a second patterned photoresist layer 264 on the buffer dielectric layer 25 (as shown in FIG. 6c); and with the second patterned photoresist layer 264 serving as a mask, etching the buffer dielectric layer 25, the second isolating oxide layer 2123, the high-k dielectric layer 2122 and the first isolating oxide layer 2121 over the substrate 20, thus forming the first opening 2134 in the buffer dielectric layer 25 in the pixel region 21, in which part of the substrate 20 around a top side wall portion of the trench fill structure 212 and the entire top surface of the trench fill structure 212 are exposed. As shown in FIG. 6d, the etched second conductive metal layer 2124 remains raised over the substrate 20, and therefore a top side wall portion of the second conductive metal layer 2124 is also exposed in the first opening 2134.

The second patterned photoresist layer is removed after the formation of the first opening.

In step S15, a first conductive metal layer is filled in the first opening so as to be electrically connected to the exposed part of the substrate 20, the exposed portion of the trench fill structure 212, or both.

When only part of the substrate 20 is exposed in the first opening, the first conductive metal layer is electrically connected to only the exposed part of the substrate 20. When at least a top portion of the trench fill structure 212 is exposed in the first opening, in consistence with the scenarios enumerated in connection with the description of step S14, the electrical connection of the first conductive metal layer with the underlying structure includes: when the top surface of the trench fill structure 212 is raised over the top surface of the substrate 20, and if the first opening surrounds only a top side wall portion of the trench fill structure 212 (i.e., the first isolating oxide layer 2121 is exposed at the top side wall portion), electrical connection of the first conductive metal layer also with only the exposed part of the substrate 20; when only the top surface of the fill material in the trench fill structure 212 is raised over the top surface of the substrate 20 and the first opening surrounds only a top side wall portion of the trench fill structure 212, and if the fill material is the second conductive metal layer 2124, electrical connection of the first conductive metal layer with the second conductive metal layer 2124 at the top side wall portion of the trench fill structure 212; when the top surface of the trench fill structure 212 is raised over or flush with the top surface of the substrate 20 and the first opening 214 resides on the top surface of the fill material in the trench fill structure 212, and if the fill material is the second conductive metal layer 2124, electrical connection of the first conductive metal layer with the partially or entirely exposed top surface of the second conductive metal layer 2124 in the trench fill structure 212; when the top surface of the trench fill structure 212 is raised over the top surface of the substrate 20, and if the first opening 214 exposes both the isolating oxide layer 2121 or the second conductive metal layer 2124 at a top side wall portion of the trench fill structure 212 and part or the entirety of the top surface of the second conductive metal layer 2124, electrical connection of the first conductive metal layer with both the part of the substrate 20 and the second conductive metal layer 2124.

In consistence with the various scenarios of exposure of the underlying structure in the first opening in step S14, methods for forming the first conductive metal layer on the buffer dielectric layer 25 corresponding to the different method of forming the first opening may include those as detailed below.

Referring to FIG. 3g, the formation of the first conductive metal layer 271 on the buffer dielectric layer 25 may include the steps of: first, forming the first conductive metal layer 271 so that it covers the buffer dielectric layer 25 and fills up the first opening 2131; and then performing an etching or chemical mechanical polishing process to remove the first conductive metal layer 271 above the surface of the substrate 20, with the first conductive metal layer 271 in the first opening 2131 being retained, which is electrically connected to the part of the substrate 20 around the top side wall portion of the trench fill structure 212 and the entire top surface of the trench fill structure 212 (i.e., the top surface of all the conductive material in the trench fill structure 212), both exposed in the first opening 2131.

Alternatively, referring to FIG. 4c, the formation of the first conductive metal layer 272 on the buffer dielectric layer 25 may include the steps of: first, forming the first conductive metal layer 272 so that it covers the buffer dielectric layer 25 and fills up the first opening 2132; and then performing an etching or chemical mechanical polishing process to remove the first conductive metal layer 272 above the surface of the substrate 20, with the first conductive metal layer 272 in the first opening 2132 being retained, which is electrically connected to the part of the top surface of the second conductive metal layer 2124 in the trench fill structure 212 exposed in the first opening 2132.

Alternatively, referring to FIG. 5c, the formation of the first conductive metal layer 273 on the buffer dielectric layer 25 may include the steps of: first, forming the first conductive metal layer 273 so that it covers the buffer dielectric layer 25 and fills up the first opening 2133; and then performing an etching or chemical mechanical polishing process to remove the first conductive metal layer 273 above the surface of the substrate 20, with the first conductive metal layer 273 in the first opening 2133 being retained, which is electrically connected to the part of the substrate 20 around the top side wall portion of the trench fill structure 212 exposed in the first opening 2133.

Alternatively, referring to FIG. 6e, the formation of the first conductive metal layer 274 on the buffer dielectric layer 25 may include the steps of: first, forming the first conductive metal layer 274 so that it covers the buffer dielectric layer 25 and fills up the first opening 2134; and then performing an etching or chemical mechanical polishing process to remove the first conductive metal layer 274 above the surface of the substrate 20, with the first conductive metal layer 274 in the first opening 2134 being retained, which is electrically connected to the part of the substrate 20 around the top side wall portion of the trench fill structure 212 and the entire top surface of the trench fill structure 212, both exposed in the first opening 2134, and is in contact with the a top side wall portion of the second conductive metal layer 2124.

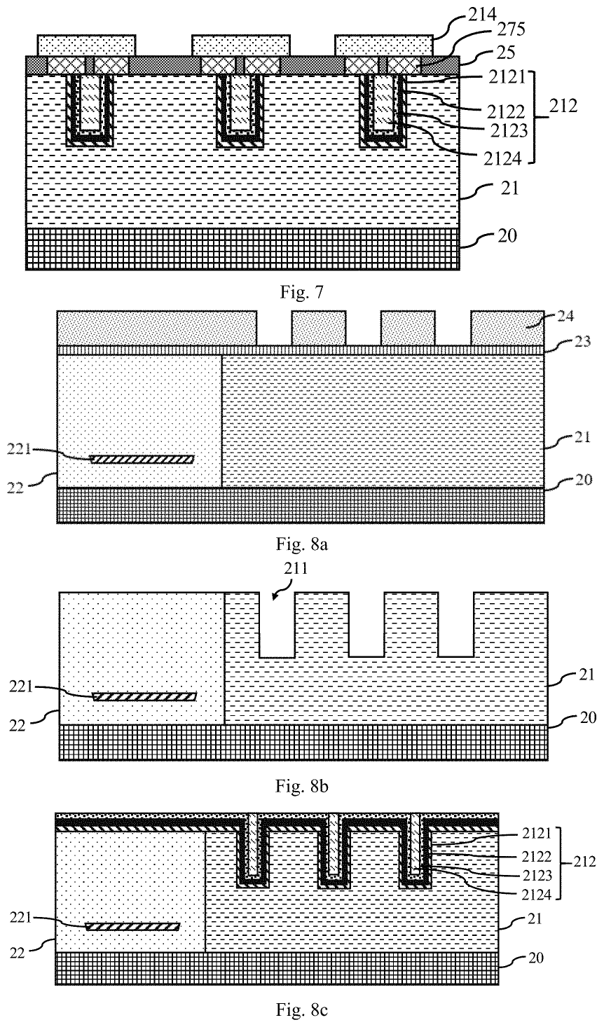

Alternatively, as shown in FIG. 7, the first conductive metal layer 275 may be electrically connected to the part of the substrate 20 around the top side wall portion of the trench fill structure 212 and part of the top surface of the second conductive metal layer 2124 in the trench fill structure 212, both exposed in the first opening 2134.

In step S16, a metal grid layer 214 is formed on the buffer dielectric layer 25 so as to be electrically connected to the first conductive metal layer. The formation of the metal grid layer 214 on the buffer dielectric layer 25 may include the steps of: first, as shown in FIGS. 3h, 4d, 5d and 6f, forming a third conductive metal layer 28 over the buffer dielectric layer 25 so that the first conductive metal layer is embedded in the third conductive metal layer 28; subsequently, forming a third patterned photoresist layer 29 on the third conductive metal layer 28 (as shown in FIGS. 3i, 4e, 5e and 6g) and, with the third patterned photoresist layer 29 serving as a mask, etching the third conductive metal layer 28, thus forming the metal grid layer 214 in the pixel region 21, which is electrically connected to the first conductive metal layer (as shown in FIGS. 3j, 4f, 5f and 6h); and then removing the third patterned photoresist layer 29.

Each of the first conductive metal layer, the second conductive metal layer 2124 and the third conductive metal layer 28 may be formed of a material including at least one of nickel, aluminum, silver, gold, titanium and copper. The material of the first conductive metal layer may be either the same as or different from that of the second conductive metal layer 2124, and may be either the same as or different from that of the third conductive metal layer 28, and these materials may be appropriately chosen according to requirements of the process for fabricating the semiconductor device and performance requirements for the semiconductor device. For example, the materials of the first conductive metal layer and the second conductive metal layer 2124 may be tungsten, while the material of the third conductive metal layer 28 may be aluminum. Since the filling ability of tungsten is better than that of aluminum, if the first opening in the semiconductor device is required to have a small width and a large depth (i.e., a high depth-to-width aspect ratio), if aluminum is filled in the first opening, void defects may occur in the first conductive metal layer, which may lead to increased circuit resistance or even an open circuit. Moreover, the electron migration characteristics of aluminum will lead to significant electron migration in the semiconductor device, apart from void defects, thus making it problematic in terms of reliability. Therefore, it is necessary to choose a suitable material for the first conductive metal layer, in order to avoid the performance of the semiconductor device from being degraded.

Since the metal grid layer 214 is electrically connected to the first conductive metal layer which is in turn electrically connected to the exposed part of the substrate 20 and/or the exposed portion of the trench fill structure 212, the metal grid layer 214 is also electrically connected to the exposed part of the substrate 20 and/or the exposed portion of the trench fill structure 212, resulting in optimized and improved electrical performance, such as dark current performance, of the semiconductor device. Moreover, the high-k dielectric layer 2122 can additionally reduce the dark current in the semiconductor device, resulting in further optimization and improvement of the semiconductor device's electrical performance.

The substrate further has a pad region peripheral to the pixel region. In the pad region of the substrate, a metal interconnection and a plug structure overlying the metal interconnection are formed. The plug structure is electrically connected at the bottom to the metal interconnection. It is to be noted that another metal structure than the metal interconnection may be formed in the pad region of the substrate so as to be electrically connected to the bottom of the plug structure. For example, the metal structure may be a conductive contact plug electrically connected to the bottom of the plug structure. These metal structures are exemplified below by the metal interconnection.

If the high-k dielectric layer is formed in the plug structure in the pad region, the device will have increased capacitance, which will lead to a significant transmission delay (RC delay) and degradation in the performance of the semiconductor device. Therefore, the high-k dielectric layer shall not be formed in the plug structure in the pad region. Accordingly, separate formation of the trench fill structure in the pixel region and the plug structure in the pad region is necessary.

The formation of the various features in the pad region may include the steps of: subsequent to the formation of the trench fill structure and prior to the formation of the buffer dielectric layer over the surface of the substrate in the pixel region, forming the plug structure in the pad region of the substrate; forming the buffer dielectric layer on the surface of the substrate in the pixel region in such a manner that it also covers the surface of the substrate in the pad region so that the plug structure is buried in the buffer dielectric layer; at the same time when the first opening is formed by etching the buffer dielectric layer in the pixel region, further etching the buffer dielectric layer in the pad region to form a second opening in which part of a top surface of the plug structure is exposed; filling the first conductive metal layer in the first opening in such a manner that it also fills the second opening so that it is electrically connected to the top surface part of the plug structure exposed in the second opening; and at the same time when the metal grid layer is formed on the buffer dielectric layer in the pixel region, forming the pad structure on the buffer dielectric layer in the pad region so that the pad structure is electrically connected to the first conductive metal layer in the second opening.

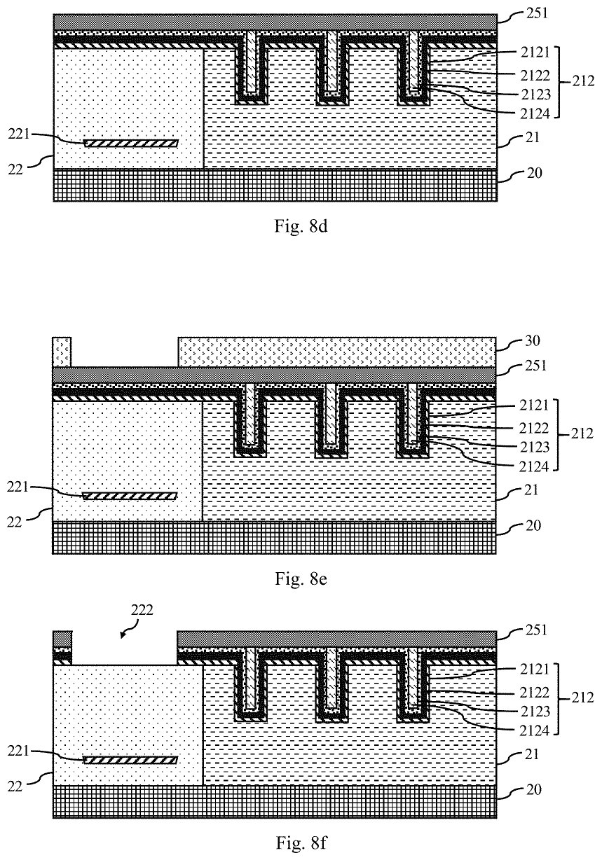

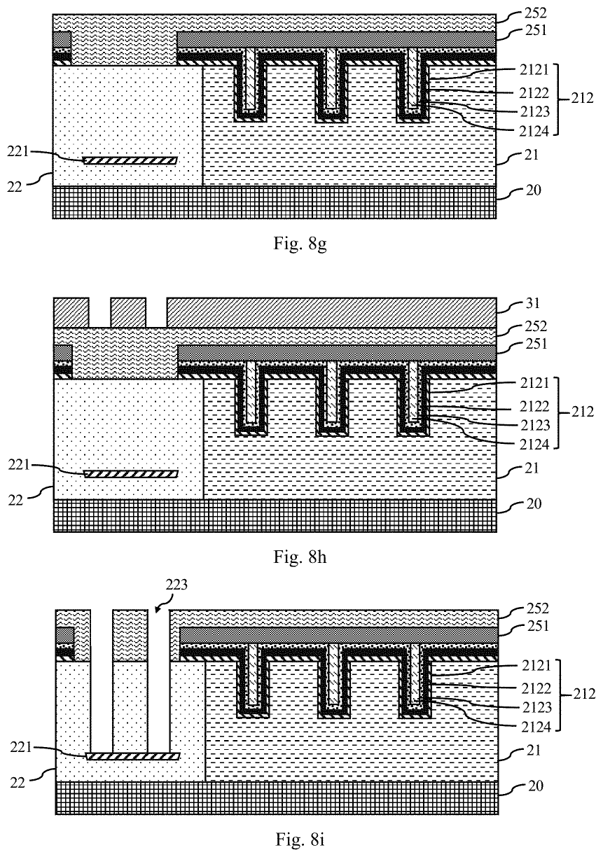

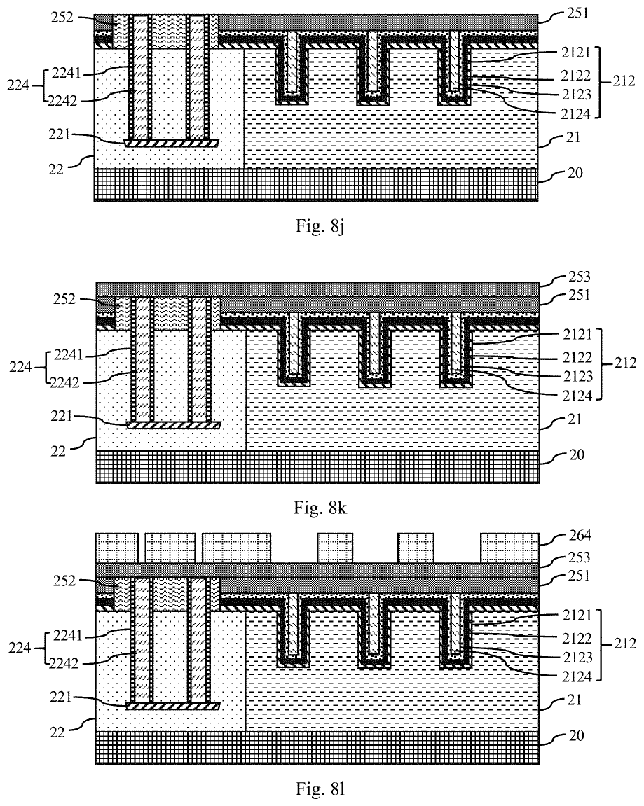

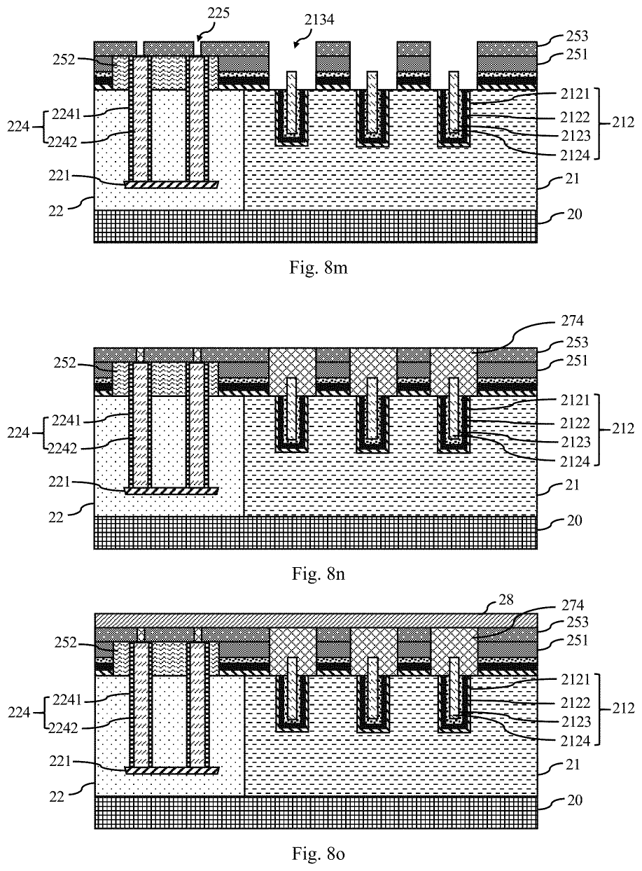

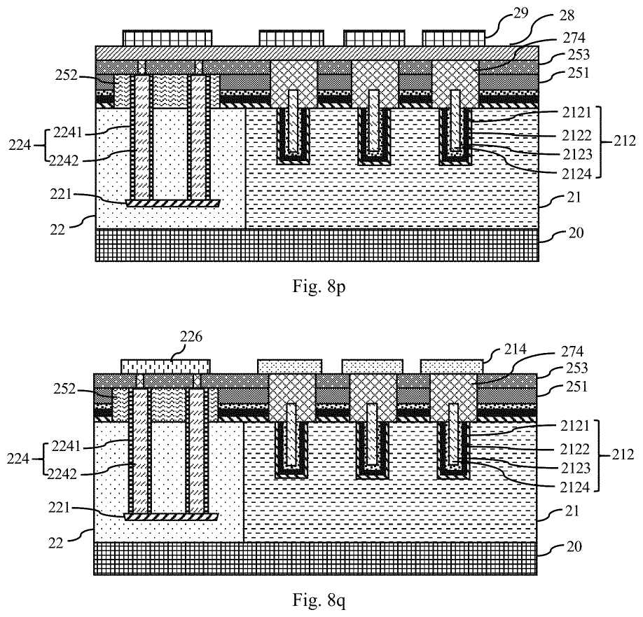

Steps involved in the formation of the trench fill structure, the first conductive metal layer and the metal grid layer in the pixel region and the plug structure, the first conductive metal layer and the pad structure in the pad region will be described below with reference to FIGS. 8a to 8q. Reference can be made to the above description of steps S11 to S16 for details in the various scenarios of electrical connection between the first conductive metal layer in the pixel region and the exposed part of the substrate and/or the exposed portion of the trench fill structure, and a further description thereof is omitted here. Taking the scenario shown in FIGS. 6a to 6h, where the first conductive metal layer 274 is electrically connected to part of the substrate 20 around a top side wall portion of the trench fill structure 212 and the entire top surface of the trench fill structure 212, both exposed in the first opening 2134, as an example, the formation of the trench fill structure 212, the first conductive metal layer 274 and the metal grid layer 214 in the pixel region 21 and the plug structure 224, the first conductive metal layer 274 and the pad structure 226 in the pad region 22 may include the steps as follows.

Referring to FIG. 8a, in step S21, a substrate 20 with a pixel region 21 and a pad region 22 is provided. The pad region 22 is peripheral to the pixel region 21. A metal interconnection 221 is formed in the pad region 22 of the substrate 20.

Referring to FIGS. 8a to 8c, in step S22, a trench 211 is formed in the pixel region 21 of the substrate 20, and a fill material is filled in the trench 211, thus forming a trench fill structure 212. A high-k dielectric layer 2122 is sandwiched between a side wall of the fill material and the substrate 20.

The step in which the trench 211 and the trench fill structure 212 are formed in the pixel region 21 of the substrate 20 includes: first, as shown in FIG. 8a, covering the surface of the substrate 20 in the pixel region 21 and the pad region 22 with a pad oxide layer 23, which is intended to protect the surface of the substrate 20 during the subsequent photolithographic formation of the first patterned photoresist layer 24; then, as shown in FIGS. 8a and 8b, forming the first patterned photoresist layer 24 on the pad oxide layer 23 and, with the first patterned photoresist layer 24 serving as a mask, etching through the pad oxide layer 23 and at least a partial thickness of the substrate 20 in the pixel region 21, thereby forming the trench 211 in the pixel region 21 of the substrate 20; subsequently, removing the first patterned photoresist layer 24 and the pad oxide layer 23; next, successively forming a first isolating oxide layer 2121, the high-k dielectric layer 2122 and a second isolating oxide layer 2123 both in the trench 211 and over the surface of the substrate 20 and filling a second conductive metal layer 2124 (i.e., the fill material) in the trench 211 so that it also covers the second isolating oxide layer 2123 surrounding the trench 211; and then performing an etching or chemical mechanical polishing process to remove the second conductive metal layer 2124 above the surface of the substrate 20 around the trench 211, thus forming the trench fill structure 212 in the trench 211. As shown in FIG. 8c, the first isolating oxide layer 2121, the high-k dielectric layer 2122 and the second isolating oxide layer 2123 remain over the substrate 20, and the top surface of the trench fill structure 212 is raised over the top surface of the substrate 20.

Referring to FIGS. 8d to 8j, in step S23, a plug structure 224 is formed in the pad region 22 of the substrate 20. The formation may include the steps of: first of all, as shown in FIG. 8d, covering the surface of the substrate 20 in the pixel region 21 and the pad region 22 with a first buffer dielectric layer 251 so that the trench fill structure 212 is embedded in the first buffer dielectric layer 251; subsequently, forming a fourth patterned photoresist layer 30 on the first buffer dielectric layer 251 (as shown in FIG. 8e) and, with the fourth patterned photoresist layer 30 serving as a mask, etching through the first buffer dielectric layer 251, the second isolating oxide layer 2123, the high-k dielectric layer 2122 and the first isolating oxide layer 2121 in the pad region 22, thus forming a third opening 222 in the first buffer dielectric layer 251 in the pad region 22 (as shown in FIG. 8f), the third opening 222 exposing part of the top surface of the substrate 20 above the metal interconnection 221; next, as shown in FIG. 8g, filling a second buffer dielectric layer 252 in the third opening 222 so that the second buffer dielectric layer 252 also covers the first buffer dielectric layer 251; after that, forming a fifth patterned photoresist layer 31 on the second buffer dielectric layer 252 (as shown in FIG. 8h) and, with the fifth patterned photoresist layer 31 serving as a mask, etching through the second buffer dielectric layer 252 and at least a partial thickness of the substrate 20 in the third opening 222, thus forming a through hole 223 extending through the second buffer dielectric layer 252 into the substrate 20 in the pad region 22, as shown in FIG. 8i, the through hole 223 exposing at least part of a top surface of the metal interconnection 221; then, forming a third isolating oxide layer 2241 on a side wall of the through hole 223 in such a manner that the third isolating oxide layer 2241 further covers the substrate 20; following that, filling up the through hole 223 with a fourth conductive metal layer 2242 which further covers the third isolating oxide layer 2241 around the through hole 223; and afterwards, performing an etching or chemical mechanical polishing process to remove the fourth conductive metal layer 2242 and the third isolating oxide layer 2241 above the substrate 20 around the through hole 223, thus forming the plug structure 224. The fourth conductive metal layer 2242 in the plug structure 224 is electrically connected at the bottom to the metal interconnection 221, as shown in FIG. 8j.

According to embodiments of the present application, forming the through hole 223 extending through the second buffer dielectric layer 252 into the substrate 20 in the pad region 22 by first forming the third opening 222 exposing part of the top surface of the substrate 20 above the metal interconnection 221, then filling the third opening 222 with the second buffer dielectric layer 252 that also covers the first buffer dielectric layer 251 and then etching through the second buffer dielectric layer 252 and at least a partial thickness of the substrate 20 in the third opening 222 enables higher accuracy and reliability of the etching processes involved in the formation of the through hole 223. In other embodiments of this application, it is also possible to directly form the through hole 223 by etching through the first buffer dielectric layer 251 and at least a partial thickness of the substrate 20, without forming the third opening 222. This can simplify the fabrication process.

Referring to FIG. 8k, in step S24, a third buffer dielectric layer 253 is formed over the surface of the substrate 20 in the pixel region 21 and the pad region 22 so as to embed the plug structure 224. As shown in FIG. 8k, it will be appreciated that the first isolating oxide layer 2121, the high-k dielectric layer 2122, the second isolating oxide layer 2123, the first buffer dielectric layer 251, the second buffer dielectric layer 252 and the third buffer dielectric layer 253, which are laminated over the substrate 20 so as to bury the trench fill structure 212 and the plug structure 224, make up the aforementioned buffer dielectric layer 25.

Referring to FIGS. 8l to 8m, in step S25, the buffer dielectric layer is etched to form therein a first opening 2134 in the pixel region 21 and a second opening 225 in the pad region 22. Part of the substrate 20 around a top side wall portion of the trench fill structure 212 and the entire top surface of the trench fill structure 212 are exposed in the first opening 2134, and part of the top surface of the plug structure 224 is exposed in the second opening 225.

The formation of the first opening 2134 and the second opening 225 may include the steps of: forming a second patterned photoresist layer 264 on the third buffer dielectric layer 253 (as shown in FIG. 8l); and, with the second patterned photoresist layer 264 serving as a mask, etching the third buffer dielectric layer 253, the first buffer dielectric layer 251, the second isolating oxide layer 2123, the high-k dielectric layer 2122 and the first isolating oxide layer 2121 in the pixel region 21, as well as the third buffer dielectric layer 253 in the pad region 22, thereby forming the first opening 2134 in the buffer dielectric layer in the pixel region 21 and the second opening 225 in the buffer dielectric layer in the pad region 22. As shown in FIG. 8m, in the first opening 2134, part of the substrate 20 around a top side wall portion of the trench fill structure 212, the entire top surface of the trench fill structure 212 and a top side wall portion of the second conductive metal layer 2124 are exposed. In the second opening 225, part of the top surface of the fourth conductive metal layer 2242 in the plug structure 224 is exposed.

Referring to FIG. 8n, in step S26, a first conductive metal layer 274 is filled in the first opening 2134 and the second opening 225 in such a manner that the first conductive metal layer 274 is electrically connected to both the part of the substrate 20 and the portion of the trench fill structure 212 exposed in the first opening 2134, and to the top surface part of the plug structure 224 exposed in the second opening 225.

The step in which the first conductive metal layer 274 is filled in the first opening 2134 and the second opening 225 includes: first, forming the first conductive metal layer 274 so that it covers the third buffer dielectric layer 253 and fills up both the first opening 2134 and the second opening 225; and then performing an etching or chemical mechanical polishing process to remove the first conductive metal layer 274 over the surface of the third buffer dielectric layer 253, with the first conductive metal layer 274 in the first opening 2134 and the second opening 225 being retained. In the first opening 2134, the first conductive metal layer 274 is electrically connected to the part of the substrate 20 around the top side wall portion of the trench fill structure 212 and the entire top surface of the trench fill structure 212, previously both exposed in the first opening 2134. Moreover, the first conductive metal layer 274 comes into contact with a top side wall portion of the second conductive metal layer 2124. In the second opening 225, the first conductive metal layer 274 is electrically connected to the top surface part previously exposed in the second opening.

Referring to FIGS. 8o to 8q, in S27, a metal grid layer 214 is formed on the third buffer dielectric layer 253 in the pixel region 21, and a pad structure 226 is formed on the third buffer dielectric layer 253 in the pad region 22. The metal grid layer 214 is electrically connected to the first conductive metal layer 274 in the first opening 2134, and the pad structure 226 is electrically connected to the first conductive metal layer 274 in the second opening 225.

The formation of the metal grid layer 214 on the third buffer dielectric layer 253 in the pixel region 21 and the pad structure 226 on the third buffer dielectric layer 253 in the pad region 22 includes the steps of: at first, as shown in FIG. 8o, forming a third conductive metal layer 28 over the third buffer dielectric layer 253 so that the first conductive metal layer 274 is buried in the third conductive metal layer 28; and then forming a third patterned photoresist layer 29 on the third conductive metal layer 28 (as shown in FIG. 8p) and, with the third patterned photoresist layer 29 serving as a mask, etching the third conductive metal layer 28, thus forming the metal grid layer 214 in the pixel region 21 and the pad structure 226 in the pad region 22 (as shown in FIG. 8q). The metal grid layer 214 is electrically connected to the first conductive metal layer 274 in the first opening 2134, and the pad structure 226 is electrically connected to the first conductive metal layer 274 in the second opening 225.

Since the first conductive metal layer 274 is electrically connected to the exposed top surface part of the plug structure 224 in the second opening 225 and the pad structure 226 to the first conductive metal layer 274 in the second opening 225, the pad structure 226 is electrically connected to the exposed top surface part of the plug structure 224.

Further, in the above method, the individual steps are not limited to being performed in the above-described sequential order, and the order may be adapted as appropriate.

In summary, the semiconductor device fabrication method provided in the present invention includes: providing a substrate with a pixel region; forming a trench in the pixel region of the substrate and filling the trench with a fill material, thus forming a trench fill structure, wherein a high-k dielectric layer is sandwiched between a side wall of the fill material and the substrate; covering a surface of the substrate in the pixel region with a buffer dielectric layer so that the trench fill structure is embedded in the buffer dielectric layer; etching the buffer dielectric layer to form a first opening exposing at least part of the substrate around a top side wall portion of the trench fill structure and/or at least a top portion of the trench fill structure; filling a first conductive metal layer in the first opening so that the first conductive metal layer is electrically connected to the exposed part of the substrate and/or the exposed portion of the trench fill structure; and forming a metal grid layer on the buffer dielectric layer so that the metal grid layer is electrically connected to the first conductive metal layer. In this method, electrically connecting the metal grid layer to the exposed part of the substrate and/or the exposed portion of the trench fill structure optimizes and improves electrical performance of the semiconductor device.

In an embodiment of the present invention, there is also provided a semiconductor device including a substrate, a trench fill structure, a buffer dielectric layer, a first conductive metal layer and a metal grid layer. The substrate has a pixel region. The trench fill structure is formed in the pixel region of the substrate and includes a fill material filled in a trench in the substrate and a high-k dielectric layer sandwiched between a side wall of the fill material and the substrate. The buffer dielectric layer is formed over a surface of the substrate in the pixel region and has a first opening exposing at least part of the substrate around a top side wall portion of the trench fill structure and/or at least a top portion of the trench fill structure. The first conductive metal layer is filled in the first opening so as to be electrically connected to the exposed part of the substrate and/or the exposed portion of the trench fill structure. The metal grid layer is formed on the buffer dielectric layer so as to be electrically connected to the first conductive metal layer.

The semiconductor device provided in the present embodiment will be described in greater detail below with reference to FIGS. 3j, 4f, 5f, 6h, 7 and 8q.

The substrate 20 with the pixel region 21 may be any suitable material well known to those skilled in the art. For more details in this regard, reference can be made to the description of step S11, and a further description thereof is omitted here.

The trench fill structure 212 is formed in the pixel region 21 of the substrate 20 and includes the fill material filled in the trench 211 in the substrate 20 and the high-k dielectric layer 2122 sandwiched between the side wall of the fill material and the substrate 20. The trench 211 may be a deep trench with a depth of 1-5 μm. It is to be noted that the depth of the trench 211 is not limited to being within the above range and may be appropriately determined according to performance requirements for the semiconductor device. The trench fill structure 212 may serve to isolate components in the pixel region 21 of the substrate 20. The high-k dielectric layer 2122 is preferred to have a k (dielectric permittivity) value of greater than 7. Materials from which the high-k dielectric layer 2122 can be made may include, but are not limited to, nitrides and metal oxides such as silicon nitride, silicon oxynitride, titanium dioxide, tantalum pentoxide, etc. The high-k dielectric layer 2122 operates at a voltage in a different band and has different charge properties and can thus change the charge in the substrate 20 and reduce a dark current that may produce noise harmful to the performance of the semiconductor device.

The trench fill structure 212 may include a first isolating oxide layer 2121, the high-k dielectric layer 2122 and a second isolating oxide layer 2123, which are sequentially stacked over a surface of the trench 211 in the substrate 20, and the fill material filled in the trench 211. The first isolating oxide layer 2121, the high-k dielectric layer 2122 and the second isolating oxide layer 2123 are arranged at least between the side wall of the fill material and the substrate 20. That is, the first isolating oxide layer 2121, the high-k dielectric layer 2122 and the second isolating oxide layer 2123 in the trench 211 may reside either on only a side wall of the trench 211 or on both the side wall and a bottom wall of the trench 211.

The fill material may include a dielectric material, or a metallic material, or both. When the fill material is a metallic material, as shown in FIG. 3j, the trench fill structure 212 includes the first isolating oxide layer 2121, the high-k dielectric layer 2122 and the second isolating oxide layer 2123, all formed over the surface of the trench 211, and a second conductive metal layer 2124 that fills up the trench 211 (i.e., the fill material provides the second conductive metal layer 2124). The dielectric material may include at least one of silica, silicon nitride, ethyl silicate, borosilicate glass, phosphosilicate glass, boro-phospho-silicate glass and silicon oxynitride, and the metallic material may include at least one of tungsten, nickel, aluminum, silver, gold and titanium.

Additionally, a top surface of the trench fill structure 212 may be flush with the top surface of the substrate 20. Alternatively, the top surface of the trench fill structure 212 may be higher than the top surface of the substrate 20. Alternatively, only a top surface of the fill material in the trench fill structure 212 may be higher than the top surface of the substrate 20.

The buffer dielectric layer 25 is formed on the surface of the substrate 20 in the pixel region 21. The buffer dielectric layer 25 has the first opening exposing at least part of the substrate 20 around a top side wall portion of the trench fill structure 212, at least a top portion of the trench fill structure 212, or both.

The exposure of at least part of the substrate 20 around a top side wall portion of the trench fill structure 212 in the first opening 214 means that the first opening 214 is so formed as to at least surround the top of the trench fill structure 212 so that at least part of the substrate 20 around the top of the trench fill structure 212 is exposed.

The exposure of at least a top portion of the trench fill structure 212 in the first opening 214 may include: when the top surface of the trench fill structure 212 is raised over the top surface of the substrate 20, and if the first opening surrounds only the top side wall portion of the trench fill structure 212 so that the first isolating oxide layer 2121 is exposed at the top side wall portion of the trench fill structure 212, exposure of also part of the substrate 20 around the top side wall portion of the trench fill structure 212 in the first opening 214; when only the top surface of the fill material in the trench fill structure 212 is raised over the top surface of the substrate 20, and if the first opening 214 surrounds only the top side wall portion of the trench fill structure 212, exposure of the fill material in the trench fill structure 212 at the top side wall portion; when the top surface of the trench fill structure 212 is raised over or flush with the top surface of the substrate 20, and if the first opening 214 resides on the top surface of the trench fill structure 212, exposure of part or the entirety of the top surface of the trench fill structure 212, including exposure of part or the entirety of the top surface of the fill material, or exposure of both part or the entirety of the top surface of the fill material and part or the entirety of top surface(s) of the first isolating oxide layer 2121 and/or the high-k dielectric layer 2122 and/or the second isolating oxide layer 2123; and when the top surface of the trench fill structure 212 is raised over the top surface of the substrate 20, exposure of both the first isolating oxide layer 2121, the high-k dielectric layer 2122, the second isolating oxide layer 2123 or the fill material in the trench fill structure 212 at the top side wall portion and part or the entirety of the top surface of the trench fill structure 212.

When the fill material includes the second conductive metal layer 2124, the exposure of at least a top portion of the trench fill structure 212 in the first opening may include: exposure of the second conductive metal layer 2124 at the top side wall portion of the trench fill structure 212 in the first opening 214 that is so formed as to surround the top side wall portion of the trench fill structure 212; or exposure of part or the entirety of the top surface of the second conductive metal layer 2124 in the trench fill structure 212 in the first opening 214 that resides on the top surface of the trench fill structure 212; or exposure of both the second conductive metal layer 2124 in the trench fill structure 212 at the top side wall portion and part or the entirety of the top surface of the second conductive metal layer 2124 in the trench fill structure 212 in the first opening 214.

The first conductive metal layer is so filled in the first opening as to be electrically connected to the exposed part of the substrate 20, the exposed portion of the trench fill structure 212, or both.

When only part of the substrate 20 is exposed in the first opening, the first conductive metal layer is electrically connected to only the exposed part of the substrate 20. When at least a top portion of the trench fill structure 212 is exposed in the first opening, in consistence with the scenarios enumerated in connection with the description of step S14, the electrical connection of the first conductive metal layer with the underlying structure includes: when the top surface of the trench fill structure 212 is raised over the top surface of the substrate 20, and if the first opening surrounds only a top side wall portion of the trench fill structure 212 (i.e., the first isolating oxide layer 2121 is exposed at the top side wall portion), electrical connection of the first conductive metal layer also with only the exposed part of the substrate 20; when only the top surface of the fill material in the trench fill structure 212 is raised over the top surface of the substrate 20 and the first opening surrounds only a top side wall portion of the trench fill structure 212, and if the fill material is the second conductive metal layer 2124, electrical connection of the first conductive metal layer with the second conductive metal layer 2124 at the top side wall portion of the trench fill structure 212; when the top surface of the trench fill structure 212 is raised over or flush with the top surface of the substrate 20 and the first opening 214 resides on the top surface of the fill material in the trench fill structure 212, and if the fill material is the second conductive metal layer 2124, electrical connection of the first conductive metal layer with the partially or entirely exposed top surface of the second conductive metal layer 2124 in the trench fill structure 212; when the top surface of the trench fill structure 212 is raised over the top surface of the substrate 20, and if the first opening 214 exposes both the isolating oxide layer 2121 or the second conductive metal layer 2124 at a top side wall portion of the trench fill structure 212 and part or the entirety of the top surface of the second conductive metal layer 2124, electrical connection of the first conductive metal layer with both the part of the substrate 20 and the second conductive metal layer 2124.

Exemplary scenarios of the electrical connection of the first conductive metal layer with the exposed part of the substrate 20 and/or the exposed portion of the trench fill structure 212 may include: as shown in FIG. 3j, electrical connection of the first conductive metal layer 271 with part of the substrate 20 around a top side wall portion of the trench fill structure 212 and the entire top surface of the trench fill structure 212, both exposed in the first opening 214; as shown in FIG. 4f, electrical connection of the first conductive metal layer 272 with part of the top surface of the second conductive metal layer 2124 in the trench fill structure 212 exposed in the first opening 2132; as shown in FIG. 5f, electrical connection of the first conductive metal layer 273 with part of the substrate 20 around a top side wall portion of the trench fill structure 212 exposed in the first opening 214; as shown in FIG. 6h, electrical connection of the first conductive metal layer 274 with part of the substrate 20 around a top side wall portion of the trench fill structure 212 and the entire top surface of the trench fill structure 212, both exposed in the first opening 214, with contact of the first conductive metal layer 274 with a top side wall portion of the second conductive metal layer 2124; as shown in FIG. 7, electrical connection of the first conductive metal layer 275 with part of the substrate 20 around a top side wall portion of the trench fill structure 212 and part of the top surface of the second conductive metal layer 2124 in the trench fill structure 212, both exposed in the first opening 214.

The metal grid layer 214 is formed on the buffer dielectric layer 25 so as to be electrically connected to the first conductive metal layer.

Each of the first conductive metal layer, the second conductive metal layer 2124 and the metal grid layer 214 may be formed of a material including at least one of nickel, aluminum, silver, gold, titanium and copper. The material of the first conductive metal layer may be either the same as or different from that of the second conductive metal layer 2124, and may be either the same as or different from that of the metal grid layer 214, and these materials may be appropriately chosen according to requirements of the process for fabricating the semiconductor device and performance requirements for the semiconductor device. For example, the materials of the first conductive metal layer and the second conductive metal layer 2124 may be tungsten, while the material of the metal grid layer 214 may be aluminum. Since the filling ability of tungsten is better than that of aluminum, if the first opening in the semiconductor device is required to have a small width and a large depth (i.e., a high depth-to-width aspect ratio), if aluminum is filled in the first opening, void defects may occur in the first conductive metal layer, which may lead to increased circuit resistance or even an open circuit. Moreover, the electron migration characteristics of aluminum will lead to significant electron migration in the semiconductor device, apart from void defects, thus making it problematic in terms of reliability. Therefore, it is necessary to choose a suitable material for the first conductive metal layer, in order to avoid the performance of the semiconductor device from being degraded.

Since the metal grid layer 214 is electrically connected to the first conductive metal layer which is in turn electrically connected to the exposed part of the substrate 20 and/or the exposed portion of the trench fill structure 212, the metal grid layer 214 is also electrically connected to the exposed part of the substrate 20 and/or the exposed portion of the trench fill structure 212, resulting in optimized and improved electrical performance, such as dark current performance, of the semiconductor device. Moreover, the high-k dielectric layer 2122 can additionally reduce the dark current in the semiconductor device, resulting in further optimization and improvement of the semiconductor device's electrical performance.

The substrate further has a pad region peripheral to the pixel region. In the pad region of the substrate, a metal interconnection and a plug structure overlying the metal interconnection are formed. The plug structure is electrically connected at the bottom to the metal interconnection. It is to be noted that another metal structure than the metal interconnection may be formed in the pad region of the substrate so as to be electrically connected to the bottom of the plug structure. For example, the metal structure may be a conductive contact plug electrically connected to the bottom of the plug structure. These metal structures are exemplified below by the metal interconnection.

The plug structure includes: a third isolating oxide layer on a side wall of a through hole in which part of a top surface of the metal interconnection is exposed; and a fourth conductive metal layer which fills up the through hole. The buffer dielectric layer is so formed as to also cover the surface of the substrate in the pad region and have a second opening in which part of a top surface of the plug structure is exposed. The first conductive metal layer also fills the second opening and is electrically connected in the second opening to the top surface part of the plug structure. A pad structure is formed on the buffer dielectric layer in the pad region so as to be electrically connected to the first conductive metal layer in the second opening.

If the high-k dielectric layer is formed in the plug structure in the pad region, the device will have increased capacitance, which will lead to a significant transmission delay (RC delay) and degradation in the performance of the semiconductor device. Therefore, the high-k dielectric layer shall not be formed in the plug structure in the pad region. Accordingly, separate formation of the trench fill structure in the pixel region and the plug structure in the pad region is necessary.

The various scenarios of the electrical connection of the first conductive metal layer in the pixel region to the exposed part of the substrate and/or the exposed portion of the trench fill structure have been described above and, therefore, need not be described in further detail herein. Below, the trench fill structure 212, the first conductive metal layer 274 and the metal grid layer 2144 in the pixel region 21 and the plug structure 224, the first conductive metal layer 274 and the pad structure 226 in the pad region 22 will be described, with the scenario shown in FIG. 8q where the first conductive metal layer 274 is electrically connected to part of the substrate 20 around a top side wall portion of the trench fill structure 212 and the entire top surface of the trench fill structure 212, both exposed in the first opening 2134, as an example.

The plug structure 224 includes: the third isolating oxide layer 2241 on the side wall of the through hole 223 in which part of the top surface of the metal interconnection 221 is exposed; and the fourth conductive metal layer 2242 which fills up the through hole 223. The fourth conductive metal layer 2242 in the plug structure 224 is electrically connected at the bottom to the metal interconnection 221.

The first isolating oxide layer 2121, the high-k dielectric layer 2122, the second isolating oxide layer 2123, the first buffer dielectric layer 251, the second buffer dielectric layer 252 and the third buffer dielectric layer 253, which are laminated over the substrate 20 so as to bury the trench fill structure 212 and the plug structure 224, make up the aforementioned buffer dielectric layer 25.

The first opening 2134 is formed in the buffer dielectric layer 25 in the pixel region 21 (i.e., in the first isolating oxide layer 2121, the high-k dielectric layer 2122, the second isolating oxide layer 2123, the first buffer dielectric layer 251 and the third buffer dielectric layer 253 over the substrate 20), and the second opening 225 is formed in the buffer dielectric layer 25 in the pad region 22 (i.e., in the third buffer dielectric layer 253). The first opening 2134 exposes part of the substrate 20 around a top side wall portion of the trench fill structure 212, the entire top surface of the trench fill structure 212, and a top side wall portion of the second conductive metal layer 2124. The second opening 225 exposes part of the top surface of the fourth conductive metal layer 2242 in the plug structure 224.

The first conductive metal layer 274 is formed in the first opening 2134 and the second opening 225. The first conductive metal layer 274 is electrically connected to the part of the substrate 20 and/or the portion of the trench fill structure 212 previously exposed in the first opening 2134, and to the top surface part of the plug structure 224 previously exposed in the second opening 225.

The metal grid layer 214 (i.e., the third buffer dielectric layer 253) is formed on the buffer dielectric layer 25 in the pixel region 21, and the pad structure 226 on the buffer dielectric layer 25 in the pad region 22. The metal grid layer 214 is electrically connected to the first conductive metal layer 274 in the first opening 2134, and the pad structure 226 is electrically connected to the first conductive metal layer 274 in the second opening 225.

Since the first conductive metal layer 274 is electrically connected to the top surface part of the plug structure 224 exposed in the second opening 225 and the pad structure 226 to the first conductive metal layer 274 in the second opening 225, the pad structure 226 is electrically connected to the exposed top surface part of the plug structure 224.

In summary, the semiconductor device provided in the present invention includes: a substrate with a pixel region; a trench fill structure formed in the pixel region of the substrate, the trench fill structure including a fill material filled in a trench in the substrate and a high-k dielectric layer sandwiched between a side wall of the fill material and the substrate; a buffer dielectric layer formed on the surface of the substrate in the pixel region, the buffer dielectric layer having a first opening exposing at least part of the substrate around a top side wall portion of the trench fill structure and/or at least a top portion of the trench fill structure; a first conductive metal layer filled in the first opening so as to be electrically connected to the exposed part of the substrate and/or the exposed portion of the trench fill structure; and a metal grid layer formed on the buffer dielectric layer so as to be electrically connected to the first conductive metal layer. In the semiconductor device of the present invention, the metal grid layer is electrically connected to the exposed part of the substrate and/or the exposed portion of the trench fill structure, resulting in optimized and improved electrical performance of the semiconductor device.

The description presented above is merely that of a few preferred embodiments of the present invention and is not intended to limit the scope thereof in any sense. Any and all changes and modifications made by those of ordinary skill in the art based on the above teachings fall within the scope as defined in the appended claims.

What is claimed is:

1. A method of manufacturing a semiconductor device, comprising:
providing a substrate with a pixel region;
forming a trench fill structure in the pixel region of the substrate;
covering a surface of the substrate in the pixel region with a buffer dielectric layer so that the trench fill structure is embedded in the buffer dielectric layer;
etching the buffer dielectric layer to form a first opening exposing at least part of the substrate around a top side wall portion of the trench fill structure and/or at least a top portion of the trench fill structure;
filling a first conductive metal layer in the first opening so that the first conductive metal layer is electrically connected to the exposed part of the substrate and/or the exposed portion of the trench fill structure; and
forming a metal grid layer on the buffer dielectric layer so that the metal grid layer is electrically connected to the first conductive metal layer.

2. The method of claim 1, wherein the step of forming the trench fill structure in the pixel region of the substrate comprises:
covering the surface of the substrate in the pixel region with a pad oxide layer;
forming a first patterned photoresist layer on the pad oxide layer and, with the first patterned photoresist layer serving as a mask, etching through the pad oxide layer and at least a partial thickness of the substrate, thereby forming a trench in the pixel region of the substrate;
removing the first patterned photoresist layer and the pad oxide layer;
successively forming a first isolating oxide layer, a high-k dielectric layer and a second isolating oxide layer both in the trench and on the surface of the substrate;
filling the fill material in the trench in such a manner that the fill material also covers the second isolating oxide layer outside the trench; and
performing an etching or chemical mechanical polishing process to remove the fill material, the second isolating oxide layer, the high-k dielectric layer and the first isolating oxide layer above the surface of the substrate outside the trench, or to remove only the fill material above the surface of the substrate outside the trench, thereby forming the trench fill structure in the trench.

3. The method of claim 1, wherein the trench fill structure comprises a second conductive metal layer made of a material that is the same as a material of the first conductive metal layer, and wherein the exposure of at least a top portion of the trench fill structure in the first opening comprises: exposure of the second conductive metal layer at a top side wall portion of the trench fill structure in the first opening that is so formed as to surround the top side wall portion of the trench fill structure; and/or exposure of part or the entirety of a top surface of the second conductive metal layer in the trench fill structure in the first opening that resides on a top surface of the trench fill structure.

4. The method of claim 1, wherein the step of forming the first opening by etching the buffer dielectric layer comprises:
forming a second patterned photoresist layer on the buffer dielectric layer and, with the second patterned photoresist layer serving as a mask, etching the buffer dielectric layer, thereby forming the first opening in the buffer dielectric layer in the pixel region, the first opening exposing at least part of the substrate around a top side wall portion of the trench fill structure and/or at least a top portion of the trench fill structure; and
removing the second patterned photoresist layer.

5. The method of claim 1, wherein the step of filling the first conductive metal layer in the first opening comprises:
forming the first conductive metal layer so that it covers the buffer dielectric layer and fills up the first opening; and
performing an etching or chemical mechanical polishing process to remove the first conductive metal layer over the substrate, with the first conductive metal layer in the first opening being retained, which is electrically connected to the exposed part of the substrate and/or the exposed portion of the trench fill structure.

6. The method of claim 1, wherein the step of forming the metal grid layer on the buffer dielectric layer comprises:
forming a third conductive metal layer on the buffer dielectric layer, which is made of a material that is different from a material of the first conductive metal layer, so that the first conductive metal layer is buried in the third conductive metal layer;
forming a third patterned photoresist layer on the third conductive metal layer and, with the third patterned photoresist layer serving as a mask, etching the third conductive metal layer, thus forming the metal grid layer in the pixel region, which is electrically connected to the first conductive metal layer; and
removing the third patterned photoresist layer.

7. The method of claim 1, wherein the substrate further has a pad region peripheral to the pixel region, and wherein a metal interconnection is formed in the pad region of the substrate and a plug structure above the metal interconnection, the plug structure being electrically connected at the bottom to the metal interconnection.

8. The method of claim 7, wherein the plug structure is formed in the pad region of the substrate subsequent to the formation of the trench fill structure and prior to the covering of the surface of the substrate in the pixel region with the buffer dielectric layer.

9. The method of claim 7, wherein in the step of covering the surface of the substrate in the pixel region with the buffer dielectric layer, the buffer dielectric layer is so formed as to further cover the surface of the substrate in the pad region so that the plug structure is embedded in the buffer dielectric layer, wherein at the same time when the first opening is formed by etching the buffer dielectric layer in the pixel region, the buffer dielectric layer in the pad region is also etched to form a second opening exposing part of a top surface of the plug structure, wherein the first conductive metal layer is so filled in the first opening that it also fills the second opening and is electrically connected in the second opening to the exposed top surface part of the plug structure; and wherein at the same time when the metal grid layer is formed on the buffer dielectric layer in the pixel region, a pad structure is formed on the buffer dielectric layer in the pad region so as to be electrically connected to the first conductive metal layer in the second opening.

10. The method of claim 1, wherein the trench fill structure comprises a high-k dielectric layer, the high-k dielectric layer being sandwiched between a side wall of a fill material and the substrate.

11. A semiconductor device, comprising:
a substrate with a pixel region, the substrate comprising a trench formed in the pixel region;
a trench fill structure formed in the pixel region of the substrate;
a buffer dielectric layer formed on the surface of the substrate in the pixel region, the buffer dielectric layer comprising a first opening exposing at least part of the substrate around a top side wall portion of the trench fill structure and/or at least a top portion of the trench fill structure;
a first conductive metal layer filled in the first opening so as to be electrically connected to the exposed part of the substrate and/or the exposed portion of the trench fill structure; and
a metal grid layer formed on the buffer dielectric layer so as to be electrically connected to the first conductive metal layer.

12. The semiconductor device of claim 11, wherein the trench fill structure comprises a first isolating oxide layer, a high-k dielectric layer, a second isolating oxide layer, which are sequentially stacked over a surface of a trench in the substrate, and a fill material filled in the trench, the first isolating oxide layer, the high-k dielectric layer and the second isolating oxide layer being situated at least between the side wall of the fill material and the substrate.

13. The semiconductor device of claim 11, wherein the trench fill structure comprises a second conductive metal layer made of a material that is the same as a material of the first conductive metal layer, and wherein the exposure of at least a top portion of the trench fill structure in the first opening comprises: exposure of the second conductive metal layer at a top side wall portion of the trench fill structure in the first opening that is so formed as to surround the top side wall portion of the trench fill structure; and/or exposure of part or the entirety of a top surface of the second conductive metal layer in the trench fill structure in the first opening that resides on a top surface of the trench fill structure.

14. The semiconductor device of claim 11, wherein the buffer dielectric layer comprises a first buffer dielectric layer, a second buffer dielectric layer and a third buffer dielectric layer.

15. The semiconductor device of claim 11, wherein the trench fill structure comprises a high-k dielectric layer, the high-k dielectric layer being sandwiched between a side wall of a fill material and the substrate.

16. The semiconductor device of claim 15, wherein the high-k dielectric layer has a k value of greater than 7.

17. The semiconductor device of claim 11, wherein the substrate further has a pad region peripheral to the pixel region, and wherein a metal interconnection is formed in the pad region of the substrate and a plug structure above the metal interconnection, the plug structure being electrically connected at the bottom to the metal interconnection.

18. The semiconductor device of claim 17, wherein a through hole is formed in the pad region of the substrate, the through hole exposing at least part of a top surface of the metal interconnection, and wherein the plug structure comprises a third isolating oxide layer on a side wall of the through hole and a fourth conductive metal layer which fills up the through hole.

19. The semiconductor device of claim 17, wherein the buffer dielectric layer further covers the surface of the substrate in the pad region and comprises a second opening exposing at least a top portion of the plug structure, wherein the first conductive metal layer is further filled in the second opening so as to be electrically connected in the second opening to the exposed top surface part of the plug structure, and wherein a pad structure is formed on the buffer dielectric layer in the pad region so as to be electrically connected to the first conductive metal layer in the second opening.

20. The semiconductor device of claim 13, wherein the materials of the first conductive metal layer and the second conductive metal layer are tungsten, while the material of the metal grid layer is aluminum.
